(19) United States
(12) Patent Application Publication
(10) Pub. No.: US 2025/0159976 A1
(43) Pub. Date: May 15, 2025

(54) DRIVING CIRCUIT, PRECHARGING CIRCUITRY FOR DRIVING CIRCUIT, AND METHOD OF OPERATING DRIVING CIRCUIT

(71) Applicant: TAIWAN SEMICONDUCTOR MANUFACTURING COMPANY, LTD., Hsinchu (TW)

(72) Inventors: Yi-An LAI, Hsinchu (TW); Chan-Hong CHERN, Hsinchu (TW)

(21) Appl. No.: 18/611,042

(22) Filed: Mar. 20, 2024

Related U.S. Application Data
(60) Provisional application No. 63/598,363, filed on Nov. 13, 2023.

(51) Int. Cl. H01L 27/088; H01L 27/06; H01L 29/20; H01L 29/778

(52) U.S. Cl. CPC H10D 84/84; H10D 30/4755; H10D 62/8503; H10D 84/811

(57) ABSTRACT

A driving circuit includes a driving stage, and a first subcircuit. The driving stage includes a first driving device and a second driving device configured to drive a power device. The first subcircuit is electrically connected to the driving stage. The first subcircuit includes a first precharge circuit and a first predriving circuit. The first predriving circuit is electrically connected to the first precharge circuit and the first driving device. The first precharge circuit is configured to, in response to an input signal of the driving circuit having a first signal level, generate a first precharging voltage. The first precharge circuit is further configured to, in response to the input signal having a second signal level different from the first signal level, fully turn on, based on the first precharging voltage, a first predriving device in the first predriving circuit to drive the first driving device.

### CROSS-REFERENCE TO RELATED APPLICATION(S)

This application claims the benefit of U.S. Provisional Application No. 63/598,363, filed Nov. 13, 2023, the entire disclosure of which is incorporated by reference herein.

### BACKGROUND

GaN-on-Si technology represents a promising advancement in power devices for the next generation. The GaN-based high-electron-mobility transistors (HEMTs) have better performance compared to their silicon-based counterparts, including the ability to operate at higher frequencies, power supply voltages, and temperatures. However, due to lack of P-type GaN-based HEMTs in the GaN process, it would be challenging for designers to develop a GaN-based driving circuit.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a schematic diagram of a driving circuit in accordance with an embodiment of the present disclosure.

FIG. 2 is a schematic diagram of a driving circuit in accordance with another embodiment of the present disclosure.

FIG. 3 is a waveform diagram of the output voltages of various driving circuits.

FIGS. 4A-4C are cross sections of different HEMTs in accordance with an embodiment of the present disclosure.

FIGS. 4D-4E are cross sections of HEMTs in different diode-connected configurations in accordance with different embodiments of the present disclosure.

FIG. 5 is a cross section of a silicon-based transistor in accordance with an embodiment of the present disclosure.

FIG. 6 is a schematic diagram of a driving circuit in accordance with yet another embodiment of the present disclosure.

FIG. 7 is a flowchart of a method of operating a driving circuit in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Source/drain(s) may refer to a source or a drain, individually or collectively dependent upon the context.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In comparison with silicon-based metal-oxide-semiconductor field-effect transistors (silicon-based MOSFET), the GaN-based HEMTs exhibit a lower threshold voltage and smaller source-drain on-state resistance. These characteristics result in reduced gate driving power requirements and increased current and switching frequency capabilities. However, the low mobility of P-type HEMTs in integrated circuits manufactured using the GaN process prompts the inclusion of enhance-mode N-type HEMTs and depletion-mode N-type HEMTs in driving circuits, in accordance with some embodiments.

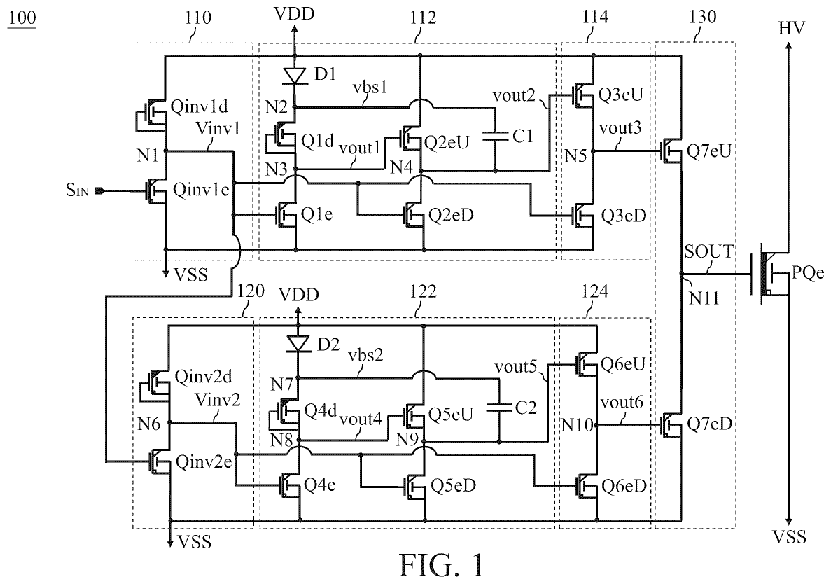

FIG. 1 is a schematic diagram of a driving circuit in accordance with an embodiment of the present disclosure.

In some embodiments, the driving circuit 100 may be disposed in an integrated circuit (IC) which is fabricated using a Group III-V process such as a GaN process. As depicted in FIG. 1, the driving circuit 100 may be configured to drive a power E-HEMT PQe (i.e., an enhancement-mode N-type power HEMT) which is supplied with a high voltage (HV), such as approximately 650V. The driving circuit 100 may include inverters 110 and 120, precharge circuits 112 and 122, predriving circuits 114 and 124, and a driving stage 130 that are in the same power domain (i.e., the power supply voltage VDD). More specifically, the driving circuit 100 may include balanced precharging circuitry to provide a high boost driving voltage to the predriving circuits 114 and 124, the details of which will be described later. In at least one embodiment, transistors in the predriving circuits 114, 124 and other predriving circuits described herein are examples of predriving devices, and transistors in the driving stage 130 and other driving stages described herein are examples of driving devices.

In some embodiments, since the driving circuit 100 does not include any P-type (i.e., P-channel) HEMT, the types of the HEMTs (i.e., channel types within the HEMTs) are not specifically labeled in FIG. 1. In addition, enhancement-mode HEMTs (abbreviated as E-HEMT) and depletion-mode HEMTs (abbreviated as D-HEMT) are represented by lower cases “e” and “d” in the reference numerals of the HEMTs, respectively. Moreover, two enhancement-mode HEMTs of the same transistor pair may include a high-side HEMT and a low-side HEMT, denoted as capital letters “U” and “D” at the end of the reference numerals of the HEMTs, respectively. For example, Q1e and Q1d may represent the E-HEMT and D-HEMT of transistor pair 1, while Q2eU and Q2eD may represent the high-side E-HEMT and low-side E-HEMT of transistor pair 2, respectively. The location and/or modes of other HEMTs in FIG. 1 can be determined in a similar manner. It should be noted that each D-HEMT in FIG. 1 may have a gate connected to its source, resulting in each D-HEMT being turned on due to a negative threshold voltage thereof. In this situation, each D-HEMT may function as a resistor, leading to a current-resistance (IR) drop across its drain and source.

In some embodiments, the capacitors C1 and C2 may be fabricated using the metal-insulator-metal (MIM) or metal-oxide-metal (MOM) technique in the BEOL (back-end of line) stage of the GaN process, but the present disclosure is not limited thereto.

In some embodiments, the inverter 110 may be an input stage of the upper portion of the driving circuit 100, which includes an E-HEMT Qinv1e and a D-HEMT Qinv1d. Although these two N-type HEMTs are in different modes, the E-HEMT Qinv1e and D-HEMT Qinv1d can operate as an inverter similar to a CMOS inverter, which includes an N-type transistor and a P-type transistor. The inverter 110 may receive an input signal S_{IN}, which may be a control signal or an oscillation signal, and generate a voltage Vinv1 at its output terminal (e.g., node N1). The voltage Vinv1 may be used to control the E-HEMTs Q1e, Q2eD, and Q3eD in the subsequent stages. In addition, the voltage Vinv1 may be provided to the inverter 120 which is an input stage of the lower portion of the driving circuit 100. In some embodiments, the voltage Vinv1 and other voltages with the label “Vinv” described herein are examples of voltage signals.

In some embodiments, the precharge circuit 112 may be configured to generate a boost voltage (e.g., voltage vout2 at node N4) for use in the predriving circuit 114. In some embodiments, the input signal S_{IN} is a digital signal that is either in the low logic state (e.g., logic 0) or the high logic state (e.g., logic 1). When the input signal S_{IN} is in the low logic state, E-HEMT Qinv1e is turned off. Since D-HEMT Qinv1d is turned on, the voltage Vinv1 at node N1 may be equal to the power supply voltage VDD minus the voltage drop across the D-HEMT Qinv1d, and it is in the high logic state capable of turning on E-HEMTs Q1e, Q2eD, and Q3eD. Consequently, the voltage vout2 at node N4 is pulled down to the ground voltage VSS, and the voltage vbs1 at node N2 may be equal to the power supply voltage VDD (e.g., 6V) minus the threshold voltage (e.g., 0.2V) VD of diode D1. Accordingly, the capacitor C1 may store a voltage approximately equal to VDD−VD (e.g., 5.8V) across its two terminals. In at least one embodiment, a low logic state is an example of one of a first signal level and a second signal level, and a high logic state is an example of the other of the first signal level and the second signal level. In some embodiments, the voltage vbs1 and other voltages with the label “vbs” described herein are examples of precharging voltages, whereas the voltage vout2 and other voltages with the label “vout” described herein are examples of boost driving voltages, driving voltages or boost voltages.

When the input signal S_{IN} is switched to the high logic state from the low logic state, E-HEMT Qinv1e is turned on, and the voltage Vinv1 at node N1 may be pulled down to the ground voltage VSS through E-HEMT Qinv1e. Consequently, E-HEMTs Q1e, Q2eD, and Q3eD are turned off. Since the D-HEMT Q1d is turned on, the voltage vout1 at node N3 is pulled up, through D-HEMT Q1d, from the ground voltage to a voltage level approximately equal to the voltage vbs1 at node N2 minus the voltage drop (e.g., VDS_{Q1d}) across D-HEMT Q1d, thereby turning on E-HEMT Q2eU. Accordingly, the voltage level vout2 at node N4 is pulled up from the ground voltage to a voltage level approximately equal to the power supply voltage VDD minus the voltage drop (e.g., VDS_{Q2eU}) of E-HEMT Q2eU.

Since the voltage vout2 at the lower terminal (e.g., node N4) of capacitor C1 is pulled up from the ground voltage to the power supply voltage VDD minus the voltage drop (e.g., VDS_{Q2eU}) of E-HEMT Q2eU, the voltage vbs1 at the higher terminal (e.g., node N2) of capacitor C1 is boosted to a voltage level approximately equal to (VDD−VD)+(VDD−VDSQ2eU)=2*VDD−VD−VDS_{Q2eU}. Thus, the voltage level vout1 at node N3 is also boosted, allowing it to fully turn on E-HEMT Q2eU. Accordingly, the voltage VDS_{Q2eU} across the E-HEMT Q2eU may be negligible compared to the power supply voltage VDD, resulting in the voltage vout2 at node N4 being substantially equal to the power supply voltage VDD. Since E-HEMT Q3eU is driven by the voltage vout2 substantially equal to the power supply voltage, E-HEMT Q3eU can be fully turned on as well, causing the voltage vout3 at node N5 to also be substantially equal to the power supply voltage VDD. Since E-HEMT Q7eU is driven by the voltage vout3 substantially equal to the power supply voltage VDD, the output voltage SOUT at node N11 may also be substantially equal to the power supply voltage VDD, providing a high driving capability to the power E-HEMT PQe in the voltage push-up duration, in one or more embodiments. In some embodiments, a voltage is substantially equal to a power supply voltage when a difference between the voltage and the power supply voltage is negligible, e.g., equal to or less than a voltage across a fully turned on transistor. In at least one embodiment, “being substantially equal to the power supply voltage” includes “being equal to the power supply voltage.”

Specifically, the upper portion of the driving circuit 100, which includes the inverter 110, precharge circuit 112, predriving circuit 114, and E-HEMT Q7eU of the driving stage, can provide a high driving capability to the power E-HEMT PQe in the voltage push-up duration, reducing the voltage push-up duration when the input signal S_{IN} is switching or oscillating between the low logic state and the high logic state, in one or more embodiments.

The lower portion of the driving circuit 100 comprises transistors Qinv2d, Qinv2e, Q4d, Q4e, Q5eU, Q5eD, Q6eU, Q6eD, diode D2, capacitor C2, nodes N6, N7, N8, N9, N10, voltages Vinv2, vbs2, vout4, vout5, vout6, which correspond to transistors Qinv1d, Qinv1e, Q1d, Q1e, Q2eU, Q2eD, Q3eU, Q3eD, diode D1, capacitor C1, nodes N1, N2, N3, N4, N5, voltages Vinv1, vbs1, vout1, vout2, vout3 in the upper portion of the driving circuit 100. The operations of the lower portion of the driving circuit 100, which includes the inverter 120, precharge circuit 122, predriving circuit 124, and E-HEMT Q7eD of the driving stage, may be similar to those of the upper portion of the driving circuit 100 with the difference being that the input signal of the lower portion of the driving circuit 100 is voltage Vinv1 at node N1, with a logic state different from that of the input signal S_{IN}. Accordingly, the lower portion of the driving circuit 100 can provide a high driving capability to the power E-HEMT PQe in the voltage pull-down duration, reducing the voltage push-up duration when the input signal SIN is switching or oscillating between the low logic state and the high logic state, in one or more embodiments.

Therefore, since the E-HEMTs at the last stage (e.g., Q7eU and Q7eD in the driving stage) before the power E-HEMT PQe can be fully turned on using the boosted voltage generated from capacitors C1 and C2 in the precharge circuits 112 and 122. This allows the driving circuit 100 to provide a higher driving capability to the power E-HEMT PQe during positive and negative voltage cycles of the input signal S_{IN}, thereby reducing and balancing the voltage push-up duration and voltage pull-down duration of the power E-HEMT PQe and improving its switching frequency, in one or more embodiments. In at least one embodiment, a precharge circuit or precharging circuitry for a driving circuit that achieves a balance between the voltage push-up duration and voltage pull-down duration (e.g., a difference between the voltage push-up duration and the voltage pull-down duration is at or below a predetermined threshold) of a power device, such as the power E-HEMT PQe, is referred to as a balanced precharge circuit or balanced precharging circuitry.

The driving circuit 100 shown in FIG. 1 may have N-type E-mode and D-mode HEMTs, and no P-type HEMTs are used, facilitating simulation of the driving circuit 100 by the designers. In addition, one power supply voltage VDD is used in the driving circuit 100, reducing the design complexity of the driving circuit 100. Since all components including E-HEMTs, D-HEMTs, the power E-HEMT, and diodes in the driving circuit 100 can be fabricated using the GaN process, the die on which the driving circuit 100 is fabricated does not need to be connected to an external CMOS driver IC using existing co-packaging or wire bonding techniques, in one or more embodiments.

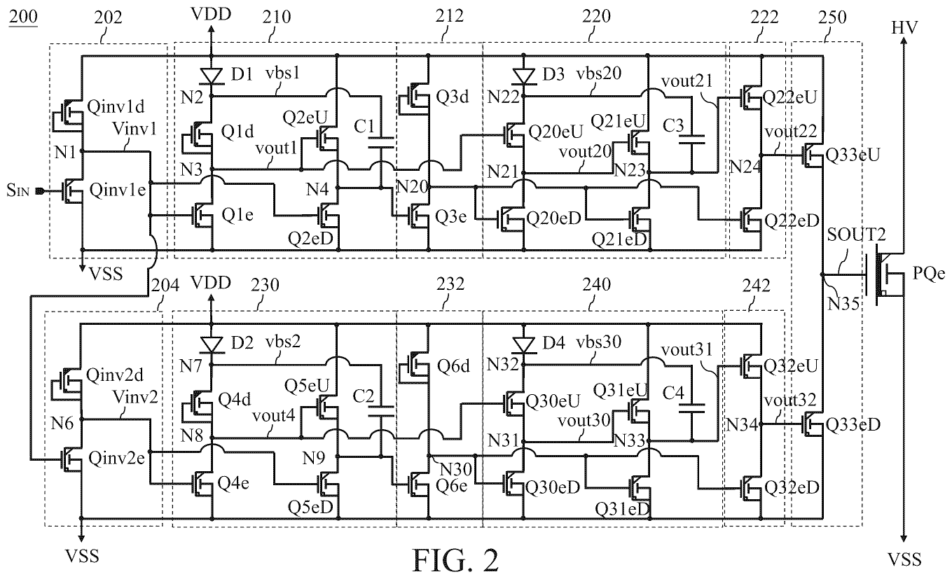

FIG. 2 is a schematic diagram of a driving circuit in accordance with another embodiment of the present disclosure.

The driving circuit 200 shown in FIG. 2 may be similar to the driving circuit 100 shown in FIG. 1, with the difference being that the driving circuit 200 includes balanced two-stage precharging circuitry, where the precharge circuits 210 and 230 may form a first stage of the balanced two-stage precharging circuitry, and the precharge circuits 220 and 240 form a second stage of the balanced two-stage precharging circuitry. In addition, the precharge circuits 210 and 230 in the first stage may be similar to the precharge circuit 112 and 122 shown FIG. 1, with the difference being that the gates of E-HEMT Q3e and Q6e shown in FIG. 2 are connected to nodes N4 and N9 rather than nodes N1 and N6, respectively. Additionally, the precharge circuits 220 and 240 in the second stage includes E-HEMTs (e.g., transistor pairs 20 to 21 and 30 to 31; transistor pair 20 indicates Q20eU and Q20eD, transistor pair 21 indicates Q21eU and Q21eD, and so forth), and no D-HEMTs are used. The operations of the driving circuit 200 are described as follows.

In some embodiments, when the input signal S_{IN} is in the low logic state, E-HEMT Qinv1e of inverter 202 is turned off. Since D-HEMT Qinv1d is turned on, the voltage Vinv1 at node N1 generated by inverter 202 may be equal to the power supply voltage VDD minus the voltage drop across the D-HEMT Qinv1d, and the voltage Vinv1 is in the high logic state capable of turning on E-HEMTs Q1e and Q2eD. Consequently, the voltage vout2 at node N4 is pulled down to the ground voltage VSS through E-HEMT Q2eD, and the voltage vbs1 at node N2 may be equal to the power supply voltage VDD (e.g., approximately 6V) minus the threshold voltage VD (e.g., approximately 0.2V) of diode D1. Accordingly, the capacitor C1 may store a voltage equal to VDD−VD (e.g., approximately 5.8V) across its two terminals (e.g., nodes N2 and N4).

With regard to the precharge circuit 220, since the voltage at node N4 is pulled down to the ground voltage VSS, HEMT Q3e is turned off. In addition, since D-HEMT Q3d is turned on, the voltage at node N20 may be pulled up to a voltage level equal to the power supply voltage VDD minus the voltage drop VDS_{Q3d} across D-HEMT Q3d, causing E-HEMTs Q20eD, Q21eD, and Q22eD to be turned on. As a result, the voltages vout20, vout21, and vout22 at nodes N21, N23, and N24 may be pulled down to the ground voltage VSS. It should be noted that the voltage vbs20 at node N22 may be equal to the power supply voltage VDD (e.g., approximately 6V) minus the threshold voltage VD (e.g., approximately 0.2V) of diode D2. Accordingly, the capacitor C3 may store a voltage equal to VDD−VD (e.g., approximately 5.8V) across its two terminals.

When the input signal S_{IN} is switched to the high logic state from the low logic state, E-HEMT Qinv1e is turned on, causing the voltage Vinv1 at node N1 to be pulled down to the ground voltage VSS through E-HEMT Qinv1e. Consequently, E-HEMTs Q1e and Q2eD are turned off. Since the D-HEMT Q1d is turned on, the voltage vout1 at node N3 is pulled up, through D-HEMT Q1d, from the ground voltage to a voltage level approximately equal to the voltage vbs1 at node N2 minus the voltage drop VDS_{Q1d} across D-HEMT Q1d, thereby turning on E-HEMT Q2eU. Accordingly, the voltage at node N4 may be pulled up from the ground voltage to a voltage level approximately equal to the power supply voltage VDD minus the voltage drop (e.g., VDS_{Q2eU}) of E-HEMT Q2eU.

Since the voltage vout2 at the lower terminal (e.g., node N4) of capacitor C1 is pulled up from the ground voltage to the power supply voltage VDD minus the voltage drop VDS_{Q2eU} of E-HEMT Q2eU, the voltage vbs1 at the higher terminal (e.g., node N2) of capacitor C1 is boosted to a voltage level approximately equal to (VDD−VD)+ (VDD−VDS_{Q2eU})=2*VDD−VD−VDS_{Q2eU}. Thus, the voltage vout1 at node N3 may also be boosted to a higher voltage level (e.g., 2*VDD−VD−VDS_{Q2eU}−VDS_{Q1d}), which is provided to E-HEMT Q20eU of the precharge circuit 220, thereby fully turning on E-HEMT Q20eU.

It should be noted that since the voltage at node N4 is pulled up to a high voltage (e.g., VDD−VDS_{Q2eU}), E-HEMT Q3e in the control circuit 212 is turned on, and the voltage at node N20 may be pulled down to the ground voltage VSS, resulting in E-HEMTs Q20eD, Q21eD, and Q22eD being turned off. Additionally, since E-HEMT Q21eU is turned on, the voltage vout21 at node N23 may be pulled up to a voltage equal to the power supply voltage VDD minus the voltage drop VDS_{Q21eU} across E-HEMT Q21eU. Since the voltage vout21 at the lower terminal (e.g., node N23) of capacitor C3 is pulled up from the ground voltage to the power supply voltage VDD minus the voltage drop VDS_{Q21eU} of E-HEMT Q21eU, the voltage vbs20 at the higher terminal (e.g., node N22) of capacitor C3 can be boosted to a voltage level approximately equal to (VDD−VD)+ (VDD−VDS_{Q21eU})=2*VDD−VD-VDS_{Q21eU}. Thus, the voltage vout20 at node N21 can also be boosted to a higher voltage level (e.g., 2*VDD−VD-VD_{SQ21eU}-VDS_{Q20eU}), where the voltage drop VDS_{Q20eU} of E-HEMT Q20eU may be negligible compared to the power supply voltage VDD because E-HEMT Q20eU is fully turned on at this time. Additionally, the voltage vout20 at node N21 may be provided to E-HEMT Q21eU of the precharge circuit 220, thereby fully turning on E-HEMT Q21eU. As a result, the voltage vout21 at node N23 can be raised to a voltage level more closer to the power supply voltage VDD, thereby fully turning on E-HEMT Q22eU in the predriving circuit 222. Since E-HEMT Q22eU is fully turned on, the voltage vout22 at node N24 can be pulled up to a voltage level substantially equal to the power supply voltage VDD, thereby fully turning on E-HEMT Q33eU in the driving stage 250. Since E-HEMT Q33eU is driven by the voltage vout22 substantially equal to the power supply voltage VDD, the output voltage SOUT2 at node N35 may also be substantially equal to the power supply voltage VDD, providing a high driving capability to the power E-HEMT PQe in the voltage push-up duration, in one or more embodiments.

It is worth noting that the driving voltage (e.g., vout21 at node N23) of high-side E-MEHT Q22eU in the predriving circuit 222 can be raised to a voltage level higher than the voltage vout1 (before the voltage vout1 is boosted by the capacitor C1) at node N3 because the high-side E-HEMT Q20eU of the precharge circuit 220 (e.g., the second stage) can have a very low voltage drop VDS_{Q21eU} due to the high-side E-HEMT Q21eU being fully turned on by the voltage vout1 at node N3 in the precharge circuit 210.

Specifically, the upper portion of the driving circuit 200 shown in FIG. 2 can provide a high driving capability to the power E-HEMT PQe in the voltage push-up duration, reducing the voltage push-up duration when the input signal S_{IN} is switched to the high logic state, in one or more embodiments.

Similarly, the lower portion of the driving circuit 200 shown in FIG. 2 may include an inverter 204, a precharge circuit 230, a control circuit 232, a precharging circuit 240, and a predriving circuit 242. Specifically, the lower portion of the driving circuit 200 comprises transistors Q6d, Q6e, Q30eU, Q30eD, Q31eU, Q31eD, Q32eU, Q32eD, diode D4, capacitor C4, nodes N30, N31, N32, N33, N34, voltages vbs30, vout30, vout31, vout32, which correspond to transistor Q3d, Q3e, Q20eU, Q20eD, Q21eU, Q21eD, Q22eU, Q22eD, diode D3, capacitor C3, nodes N20, N21, N22, N23, N24, voltages vbs20, vout20, vout21, vout22 in the upper portion of the driving circuit 200. The operations of the lower portion of the driving circuit 200 shown in FIG. 2 may be similar to those of the upper portion of the driving circuit with the difference being that the input signal of the lower portion of the driving circuit 200 is voltage Vinv1 at node N1, with a logic state different from that of the input signal SIN. Accordingly, the lower portion of the driving circuit 200 can provide a high driving capability to the power E-HEMT PQe in the voltage pull-down duration, reducing the voltage pull-down duration when the input signal S_{IN} is switched to the low logic state, in one or more embodiments. The described two-stage precharging circuitry is an example of multi-stage precharging circuitry. In some embodiments, multi-stage precharging circuitry includes more than two stages.

A driving circuit in accordance with one or more other approaches of a first type includes an inverter chain which includes a plurality of inverters connected in series. Each inverter or stage includes a high-side D-HEMT and a low-side E-HEMT. Such a driving circuit potentially suffers from one or more of the following disadvantage, such as larger static currents, long voltage push-up and pull-down durations, and low driving capability, etc. A driving circuit in accordance with some embodiments overcome one or more such disadvantages, as described herein.

A driving circuit in accordance with one or more other approaches of a second type includes an inverter chain which includes a first stage and a last stage connected in series. The first stage includes a high-side D-HEMT and a low-side E-HEMT. The last stage, which drives the power device, includes a high-side E-HEMT and low-side E-HEMT. Such a driving circuit potentially suffers from one or more of the following disadvantage, such as a lower voltage swing range, a long voltage push-up duration, and low driving capability, etc. A driving circuit in accordance with some embodiments overcome one or more such disadvantages, as described herein.

Additionally, the driving circuit in accordance with one or more other approaches of the first type or the second type described above potentially suffers from a long voltage push-up duration, resulting in a large push-pull time ratio Tr/Tf of the voltage push-up duration (Tr) and voltage pull-down duration (Tf). This can cause the voltage push-up duration (Tr) and voltage pull-down duration (Tf) of the high-side HEMT and low-side HEMT being overlapping. A long push-pull time ratio Tr/Tf can lead to a short current through the high-side HEMT and the low-side HEMT, increased hot carrier injections to the HEMTs, a lower switching frequency of the power HEMT, and higher conduction loss. For example, the short current through the high-side HEMT and the low-side HEMT can burn out the high-side HEMT and the low-side HEMT. Increased hot carrier injections to the HEMTs may result in reduced reliability. A lower switching frequency of the power HEMT may result in a big form factor (e.g., a larger product size). Higher conduction loss may indicate higher impedances of the high-side HEMT and low-side HEMT which may be caused by low driving capability of the half-bridge rectifier.

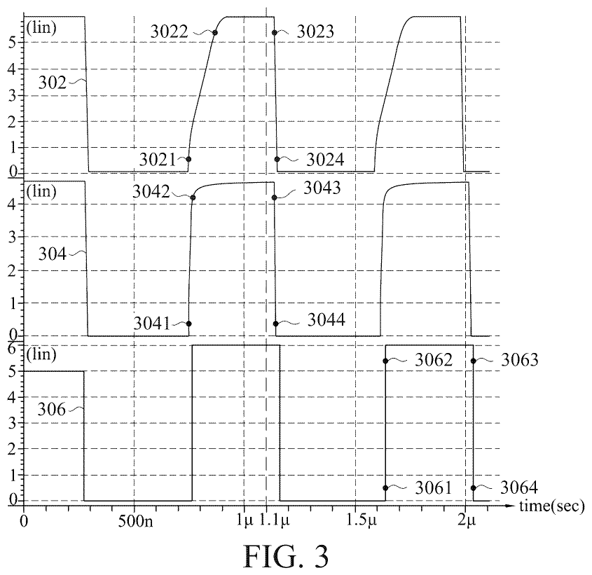

FIG. 3 is a waveform diagram of the output voltages of various driving circuits.

Curve 302 may illustrate the output voltage (e.g., the gate voltage of a power E-HEMT) of a driving circuit of the first type that includes an inverter chain for driving a power E-HEMT. Each stage or inverter includes a high-side D-HEMT and a low-side E-HEMT. Due to the limited driving capability of the high-side D-HEMT at the last stage, the voltage push-up duration of the power E-HEMT can be much longer compared to the pull-down duration due to the gate of the power E-HEMT not reaching full voltage swing and limited driving capability of the high-side D-HEMT at the last stage. As shown in FIG. 3, the voltage push-up duration from point 3021 to point 3022 may be approximately 120 ns, where points 3021 and 3022 may denote the time points at 10% and 90% of the maximum voltage swing (e.g., approximately 5.8V). The voltage push-down duration from point 3023 to point 3024 may be approximately 9.9 ns, where points 3023 and 3024 may denote the time points at 90% and 10% of the maximum voltage swing (e.g., approximately 5.8V).

Curve 304 may illustrate the output voltage (e.g., the gate voltage of a power E-HEMT) of a driving circuit of the second type that includes a first stage of a high-side D-HEMT and a low-side E-HEMT, and a last stage of a high-side E-HEMT and a low-side E-HEMT, for driving the power E-HEMT. The voltage drop across the high-side E-HEMT at the last stage can be considerable, which may be approximately equal to the threshold voltage Vt (e.g., 1.4V) of the high-side E-HEMT at the last stage. Consequently, the maximum voltage for driving the power E-HEMT PQe may be limited to approximately VDD−Vt=6−1.4=4.6V. As shown in FIG. 3, the voltage push-up duration from point 3041 to point 3042 may be approximately 18.2 ns, where points 3041 and 3042 may denote the time points at 10% and 90% of the maximum voltage swing (e.g., approximately 4.6V). The voltage push-down duration from point 3043 to point 3044 may be approximately 6.9 ns, where points 3043 and 3044 may denote the time points at 90% and 10% of the maximum voltage swing (e.g., approximately 4.6V).

Curve 306 may illustrate the output voltage (e.g., the gate voltage of power E-HEMT PQe) of the driving circuit 100 shown in FIG. 1, in one or more embodiments. For example, with the precharge circuits 112 and 122, and predriving circuits 114 and 124, the gate voltage of the E-HEMTs Q7eU and Q7eD in the driving stage 130 is approximately equal to the power supply voltage. Additionally, with increased driving capability of the predriving circuits 114 and 124, the E-HEMTs Q7eU and Q7eD in the driving stage 130 can be fully turned on when the input signal S_{IN} is positive and negative, respectively. Therefore, the voltage SOUT at node N11 (e.g., the gate voltage of power E-HEMT PQe) can be approximately equal to the power supply voltage, leading to a shorter voltage push-up duration and a shorter voltage pull-down duration. As shown in FIG. 3, the voltage push-up duration from point 3061 to point 3062 may be approximately 0.49 ns, where points 3061 and 3062 may denote the time points at 10% and 90% of the maximum voltage swing (e.g., approximately 6V) of the driving circuit 100. The voltage push-down duration from point 3063 to point 3064 may be approximately 0.40 ns, where points 3063 and 3064 may denote the time points at 90% and 10% of the maximum voltage swing (e.g., approximately 6V) of the driving circuit 100. Since the voltage push-up duration and voltage pull-down duration of the driving circuit 100 is relatively faster than those of the driving circuits described in the approaches associated with curves 302 and 304, leading to faster switching time and a higher operating frequency of the power E-HEMT PQe in FIG. 1, in one or more embodiments. The voltage push-up duration (e.g., 0.49 ns) and voltage pull-down duration (e.g., 0.40 ns) are substantially equal, which is an example result achievable by the balanced precharging circuitry of the driving circuit 100.

It should be noted that curves 302 to 306 in FIG. 3 are for purposes of illustration, and they may vary depending on the actual specification of the HEMTs, such as the power supply voltage being applied, channel width, thickness of the p-GaN layer, etc., used in the driving circuits.

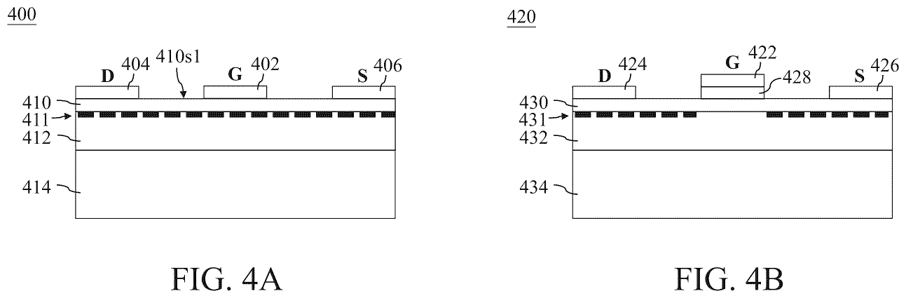

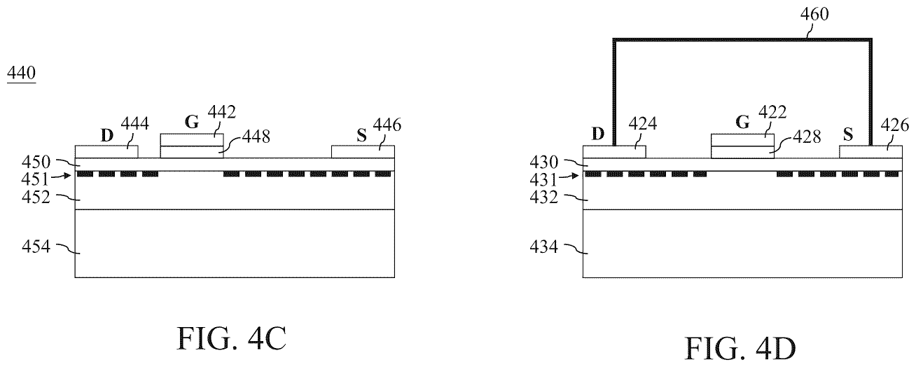

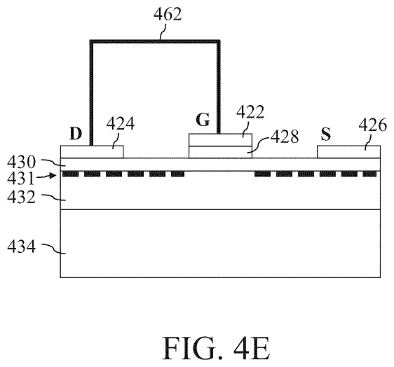

FIGS. 4A-4C are cross sections of different HEMTs in accordance with an embodiment of the present disclosure.

In some embodiments, HEMT 400 shown in FIG. 4A may be a GaN-based D-HEMT used for high-voltage applications (e.g., 12V). HEMT 400 may be implemented using a Schottky gate structure, which includes a substrate 414, GaN layer 412, and an AlGaN layer 410, as depicted in FIG. 4A. The GaN layer 412 and the AlGaN layer 410 may form a heterojunction. A gate electrode 402, drain electrode 404, and source electrode 406 (e.g., metal) may be formed on a top surface 410s1 of the AlGaN layer 410. As a voltage bias VDS is applied between the drain electrode 404 and source electrode 406 of HEMT 400, a lateral electrical field is built and the two-dimensional electron gas (2DEG) 411 under the gate electrode 402 may flow along the channel of the AlGaN/GaN heterojunction as the current I_{DS} of HEMT 400. It should be noted that HEMT 400 may have a negative threshold voltage, and it is inherently normally-ON. When a negative voltage lower than the threshold voltage of HEMT 400 is applied to the gate electrode 402, HEMT 400 may be turned off. It should be noted that positions of the drain electrode 404 and source electrode 406 with respect to the gate electrode 402 in the structure of HEMT 400 shown in FIG. 4A may be symmetrical. In some embodiments, the D-HEMTs shown in FIGS. 1 and 2 may be implemented using HEMT 400 shown in FIG. 4A.

In some embodiments, HEMT 420 shown in FIG. 4B may be a GaN-based E-HEMT used for high-voltage applications (e.g., 12V). The structure of HEMT 420 shown in FIG. 4B is similar to that of HEMT 400 shown in FIG. 4A, with the difference being that a P-type GaN (p-GaN) layer 428 is inserted between the gate electrode 422 and the AlGaN layer 430. Thus, HEMT 420 can be regarded as an E-HEMT. With high p-type doping (e.g., Mg) in the p-GaN layer 428, the 2DEG 431 below the gate electrode 422 would be depleted, which can lead to a positive threshold voltage of HEMT 420. In some embodiments, the E-HEMTs shown in FIGS. 1 and 2 may be implemented using HEMT 420 shown in FIG. 4B.

In some embodiments, the structure of HEMT 440 shown in FIG. 4C is similar to that of HEMT 420 shown in FIG. 4B, with the difference being that positions of the drain electrode 444 and source electrode 446 with respect to the gate electrode 442 in the structure of HEMT 440 shown in FIG. 4C may be asymmetrical. Specifically, the gate electrode 442 and P-type GaN layer 448 may be closer to the drain electrode 444, and a very high voltage (e.g., 650V) can be applied to the drain electrode 444 of HEMT 440 using a structure such as in FIG. 4C. In some embodiments, the power E-HEMTs shown in FIGS. 1 and 2 may be implemented using HEMT 440 shown in FIG. 4C.

FIGS. 4D-4E are cross sections of HEMTs in different diode-connected configurations in accordance with different embodiments of the present disclosure.

In some embodiments, each of diodes D1 to D4 shown in FIGS. 1 and 2 can be implemented using HEMT 420 shown in FIG. 4B. For example, as depicted in FIG. 4D, the drain electrode 424 can be electrically connected to the source electrode 426 through metal 460, causing the interface between the p-GaN layer 428 and AlGaN layer 430 to form a P-N junction of a diode with an anode being the gate electrode 442 and a cathode being the drain electrode 424 and source electrode 426. Alternatively, as depicted in FIG. 4E, the gate electrode 422 can be electrically connected to the drain electrode 424 through metal wire 462. Using the configuration shown in FIG. 4E, HEMT 420 can function as a diode with an anode being the gate electrode 422 and drain electrode 424 and a cathode being the source electrode 426.

It should be noted that the cross sections depicted in FIGS. 4A to 4E for the GaN-based E-HEMTs, D-HEMTs, and power E-HEMT are for illustrative purposes. The embodiments described in FIGS. 1 and 2 of the present disclosure can be realized using structures from existing or future developments in GaN-based E-HEMTs, D-HEMTs, and power E-HEMTs.

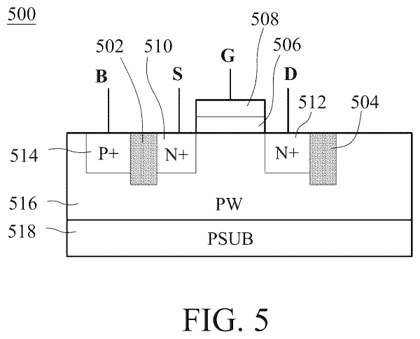

FIG. 5 is a cross section of a silicon-based transistor in accordance with an embodiment of the present disclosure.

In the example configuration in FIG. 5, a cross section of a silicon-based N-type transistor 500 is shown. It should be noted that positions of the drain electrode 512 and source electrode 510 with respect to the gate electrode 508 in the structure of silicon-based transistor 500 shown in FIG. 5 may be symmetrical. For example, the substrate 518 may be or comprise a semiconductor wafer such as a silicon wafer. Alternatively, the substrate 518 may include other elementary semiconductors such as germanium. The substrate 518 may also include a compound semiconductor such as silicon carbide, gallium arsenic, indium arsenide, or indium phosphide. The substrate 518 may include an alloy semiconductor such as silicon germanium, silicon germanium carbide, gallium arsenic phosphide, or gallium indium phosphide. In the present embodiment, the substrate 518 includes a P-type silicon wafer, which may be regarded as a P-type substrate (PSUB). The well region 516 may be a P-type well region. The bulk terminal 514 and the source terminal 510 may be separated by a shallow trench isolation (STI) region 502.

The transistor 500 may include a gate structure disposed on the well region 516 (P-well, PW), and the gate structure may include a gate dielectric 506 and a gate electrode 508 disposed on the gate dielectric 506. The gate dielectric 506 includes a silicon dioxide layer formed by thermal oxidation, chemical vapor deposition (CVD), physical vapor deposition (PVD), atomic layer deposition (ALD), or other suitable processes, or combinations thereof. Alternatively, the gate dielectric 506 may include high dielectric-constant (high-k) materials, silicon oxynitride, other suitable materials, or combinations thereof. The gate dielectric 506 may be multilayered of, for example, silicon oxide and high-k material.

The gate electrode 508 may be designed to be coupled to metal interconnects and disposed overlying the gate dielectric 506. The gate electrode 508 may include doped polycrystalline silicon (or polysilicon). Alternatively, the gate electrode 508 may include a metal such as Al, Cu, W, Ti, Ta, TiN, TaN, NiSi, CoSi, other suitable conductive materials, or combinations thereof. The gate electrode 508 may be formed by CVD, PVD, plating, and other acceptable processes. The gate electrode 508 may be multilayered and formed by a multi-step process. In some embodiments, the thickness of the gate dielectric 506 may be designed for applications using a voltage of approximately 1.8V which is lower than the voltage (e.g., 12V) used by the HEMTs 400, 420, and 440 respectively shown in FIGS. 4A-4C.

In some embodiments, the bulk terminal 514 may be a highly doped P-type implanted region (e.g., P+), and the source terminal 510 and the drain terminal 512 may be highly doped N-type implanted region (e.g., N+). In addition, another STI region 504 may be formed next to the drain terminal 512. A silicon-based P-type transistor is configured similarly, and differs from the N-type transistor 500 in different materials, dopants, or the like.

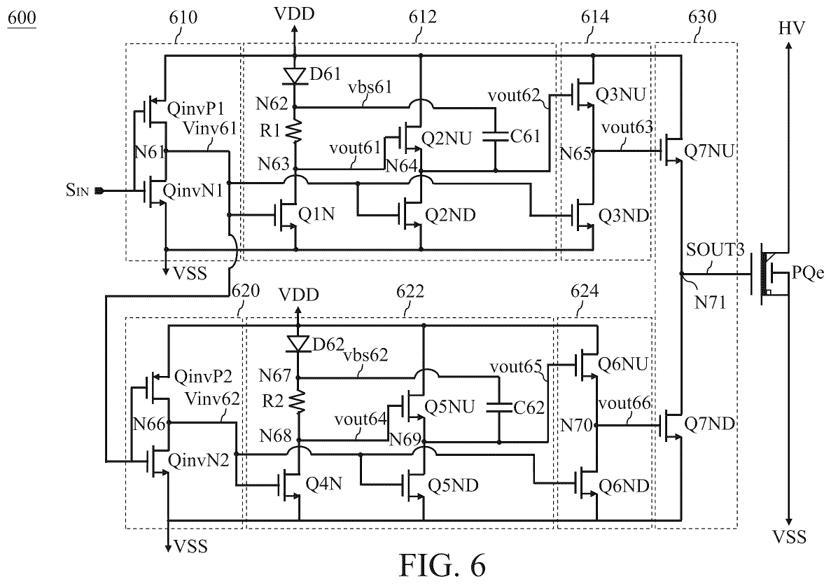

FIG. 6 is a schematic diagram of a driving circuit in accordance with yet another embodiment of the present disclosure.

The driving circuit 600 shown in FIG. 6 is an example implementation of the driving circuit 100 shown in FIG. 1, where the D-HEMTs and E-HEMTs in the driving circuit 100 are replaced with silicon-based P-type and N-type transistors, respectively. Specifically, the driving circuit 600 comprises inverters 610, 620, precharge circuits 612, 622, predriving circuits 614, 624, and a driving stage 630 which correspond to inverters 110, 120, precharge circuits 112, 122, predriving circuits 114, 124, and driving stage 130 in the driving circuit 100. An upper portion of the driving circuit 600 comprises transistors QinvP1, QinvN1, resistor R1, transistors Q1N, Q2NU, Q2ND, Q3NU, Q3ND, Q7NU, diode D61, capacitor C61, nodes N61, N62, N63, N64, N65, N71, voltages Vinv61, vbs61, vout61, vout62, vout63, SOUT3, which correspond to transistors Qinv1d, Qinv1e, Q1d, Q1e, Q2eU, Q2eD, Q3eU, Q3eD, Q7eU, diode D1, capacitor C1, nodes N1, N2, N3, N4, N5, N11, voltages Vinv1, vbs1, vout1, vout2, vout3, SOUT in the upper portion of the driving circuit 100. A lower portion of the driving circuit 600 comprises transistors QinvP2, QinvN2, resistor R2, transistors Q4N, Q5NU, Q5ND, Q6NU, Q6ND, diode D62, capacitor C62, nodes N66, N67, N68, N69, N70, voltages Vinv62, vbs62, vout64, vout65, vout66, which correspond to transistors Qinv2d, Qinv2e, Q4d, Q4e, Q5eU, Q5eD, Q6eU, Q6eD, diode D2, capacitor C2, nodes N6, N7, N8, N9, N10, voltages Vinv2, vbs2, vout4, vout5, vout6, in the lower portion of the driving circuit 100.

The configuration of the inverters 610 and 620 shown in FIG. 6 may be slightly different from the inverters 110 and 120 shown in FIG. 1. For example, each D-HEMTs (e.g., Qinv1d and Qinv2d) in the inverters 110 and 120 shown in FIG. 1 may have a gate connected to its drain, resulting in the D-HEMTs being in the ON state and functioning as a resistor. When the inverters are implemented using the CMOS transistors, the gate of the P-type transistors (e.g., QinvP1 and QinvP2) of inverters 610 and 620 shown in FIG. 6 may be connected to their respective input signals (e.g., S_{IN} for inverter 610, and Vinv1 for inverter 620). In addition, when the D-HEMTs (e.g., Q1d and Q4d) in transistor pairs 1 and 4 in the driving circuit 100 are replaced with respective resistors R1 and R2. In some embodiments, the resistors R1 and R2 can be implemented using respective P-type transistors, each P-type transistor may have a gate connected to its source, resulting in the P-type transistors being in an ON state due to their negative threshold voltage. In some embodiments, the resistors R1 and R2 can be implemented using SiCr or TiN in the BEOL stage of the GaN process, but the present disclosure is not limited thereto. The operations of the driving circuit 600 shown in FIG. 6 may be similar to those of the driving circuit 100 shown in FIG. 1, and thus the details thereof are not be repeated here.

Specifically, the technique of the balanced precharging circuitry used in the GaN-based driving circuit 100 can also be applied to the silicon-based driving circuit 600 so as to provide an improved and balanced driving capability (e.g., for positive and negative input signal S_{IN}), in one or more embodiments. It should be noted that, for purposes of description, the power device shown in FIG. 6 may be implemented by a power E-HEMT PQe similar to that in FIG. 1. In this situation, the driving circuit 600 may be fabricated in a first die using the silicon-based CMOS process, and the power E-HEMT PQe may be fabricated in a second die using the GaN process, in one or more embodiments. The first die and the second die can be stacked or wire bonded, e.g., with one of them being flipped, in one or more embodiments. In some embodiments, the power E-HEMT PQe shown in FIG. 6 can be replaced with a power FET fabricated on the first die using the silicon-based CMOS process, and thus no chip stacking or wire bonding is needed.

It should be noted that the technique of balanced two-stage precharging circuitry used in the GaN-based driving circuit 200 can also be applied to another silicon-based driving circuit (not explicitly shown) so as to provide a further improved and balance driving capability, in one or more embodiments.

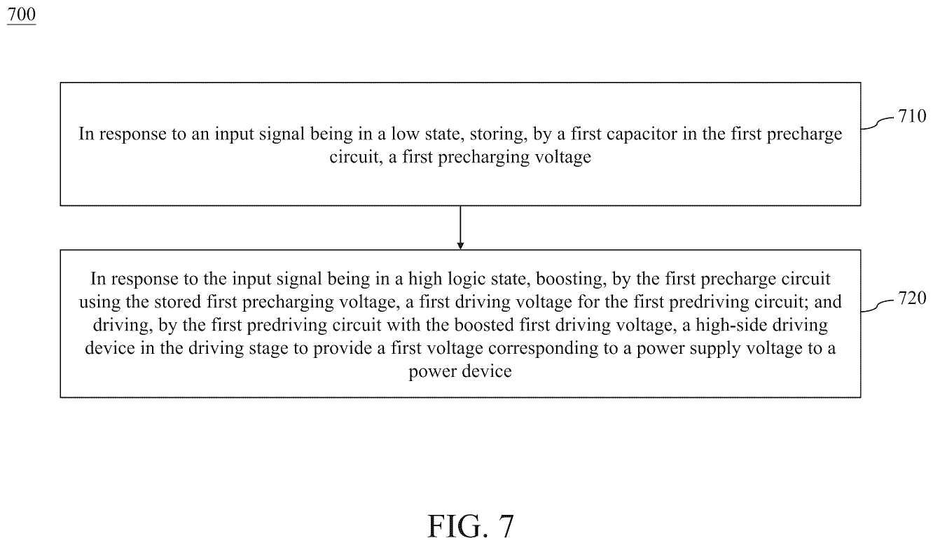

FIG. 7 is a flowchart of a method 700 for improving driving capability of a driving circuit in accordance with an embodiment of the present disclosure. Please refer to FIG. 1 and FIG. 7.

In operation 710, in response to an input signal (e.g., S_{IN}) being in a low logic state, a first precharging voltage is stored by a first capacitor (e.g., C1) in the first precharging circuit (e.g., precharge circuit 112). For example, in response to the input signal being in the low logic state, E-HEMT Qinv1e is turned off. Since D-HEMT Qinv1d is turned on, the voltage Vinv1 at node N1 may be equal to the power supply voltage VDD minus the voltage drop across the D-HEMT Qinv1d, and it is in the high logic state capable of turning on E-HEMTs Q1e, Q2eD, and Q3eD. Consequently, the voltage vout2 at node N4 is pulled down to the ground voltage VSS, and the voltage vbs1 at node N2 may be equal to the power supply voltage VDD (e.g., 6V) minus the threshold voltage (e.g., 0.2V) VD of diode D1. Accordingly, the capacitor C1 may store a voltage (e.g., the first precharging voltage) approximately equal to VDD−VD (e.g., 5.8V) across its two terminals.

In operation 720, in response to the input signal being in a high logic state, a first driving voltage (e.g., vout2) for the first predriving circuit (e.g., 114) is boosted by the first precharge circuit using the stored first precharging voltage, and a high-side driving device (e.g., E-HEMT Q7eU) in the driving stage is driven by the first precharging circuit with the boosted first driving voltage to provide a first voltage (e.g., SOUT) corresponding to a power supply voltage (e.g., VDD) to a power device (e.g., PQe). For example, the precharge circuit 112 can boost the voltage vout2 at node N4 using capacitor C1 in response to the input signal S_{IN} being switched from the low logic state to the high logic state, causing the E-HEMT Q3eU to fully turn on to provide a voltage substantially equal to the power supply voltage VDD to the high-side driving device (e.g., Q7eU). Accordingly, the high-side driving device (e.g., Q7eU) can provide a first voltage substantially equal to the power supply voltage VDD to the power device (e.g., PQe) with a high driving capability to the power device (e.g., PQe) in the voltage push-up duration.

In some embodiments, the method 700 additionally comprises the operations of the lower portion of the driving circuit 100 which may be similar to those of the upper portion of the driving circuit 100 with the difference being that the input signal of the lower portion of the driving circuit 100 is voltage Vinv1 at node N1, with a logic state different from that of the input signal S_{IN}. For example, in response to the input signal being in the high logic state, a second precharging voltage is stored by a second capacitor (e.g., C2) in the second precharge circuit (e.g., precharge circuit 122). In response to the input signal being in the low logic state, a second driving voltage (e.g., vout5) for the second predriving circuit (e.g., 124) is boosted by the second precharge circuit using the stored second precharging voltage, and a low-side driving device (e.g., Q7eD) in the driving stage is driven by the second predriving circuit with the boosted second driving voltage to provide a ground voltage (e.g., VSS).

An aspect of the present disclosure provides a driving circuit, which includes a driving stage, and a first subcircuit. The driving stage includes a first driving device and a second driving device configured to drive a power device. The first subcircuit is electrically connected to the driving stage. The first subcircuit includes a first precharge circuit and a first predriving circuit. The first predriving circuit is electrically connected to the first precharge circuit and the first driving device. The first precharge circuit is configured to, in response to an input signal of the driving circuit having a first signal level, generate a first precharging voltage. The first precharge circuit is further configured to, in response to the input signal having a second signal level different from the first signal level, fully turn on, based on the first precharging voltage, a first predriving device in the first predriving circuit to drive the first driving device.

Another aspect of the present disclosure provides multi-stage precharging circuitry for a driving circuit. The multi-stage precharging circuitry includes a first precharge circuit, and a second precharge circuit. The first precharge circuit is configured to generate a first boost driving voltage higher than a power supply voltage supplied to the multi-stage precharging circuitry, in response to an input signal having a first signal level. The second precharge circuit is electrically connected to the first precharge circuit, and configured to generate a second boost driving voltage based on the first boost driving voltage, in response to the input signal having the first signal level.

Yet another aspect of the present disclosure provides a method of operating a driving circuit. The driving circuit includes a first precharge circuit, a first predriving circuit, and a driving stage. The method includes the following steps. In response to an input signal being in a first logic state, a first precharging voltage is stored by a first capacitor in the first precharge circuit. In response to the input signal being in a second logic state different from the first logic state, a first driving voltage for the first predriving circuit is boosted by the first precharge circuit using the stored first precharging voltage, and a first driving device in the driving stage is driven by the first predriving circuit with the boosted first driving voltage to provide a first voltage corresponding to a power supply voltage to a power device.

The methods and features of the present disclosure have been sufficiently described in the provided examples and descriptions. It should be understood that any modifications or changes without departing from the spirit of the present disclosure are intended to be covered in the protection scope of the present disclosure. The various low levels and high levels described herein are example. It is within the scopes over various embodiments to modify one or more of the described circuits or signals to include a low level instead of a described high level, and vice versa. The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A driving circuit, comprising:
a driving stage, comprising a first driving device and a second driving device configured to drive a power device; and
a first subcircuit, electrically connected to the driving stage, the first subcircuit comprising:
a first precharge circuit; and
a first predriving circuit, electrically connected to the first precharge circuit and the first driving device,
wherein the first precharge circuit is configured to:
in response to an input signal of the driving circuit having a first signal level, generate a first precharging voltage, and
in response to the input signal having a second signal level different from the first signal level, fully turn on, based on the first precharging voltage, a first predriving device in the first predriving circuit to drive the first driving device.

2. The driving circuit of claim 1, further comprising:
a second subcircuit, electrically connected to the driving stage, the second subcircuit comprising:
a second precharge circuit; and
a second predriving circuit, electrically connected to the second precharge circuit and the second driving device,
wherein the second precharge circuit is configured to:
in response to the input signal having the second signal level, generate a second precharging voltage, and
in response to the input signal having the first signal level, fully turn on, based on the second precharging voltage, a second predriving device in the second predriving circuit to drive the second driving device.

3. The driving circuit of claim 2, wherein
in response to the input signal having the second signal level, the first precharge circuit is configured to boost the first precharging voltage to be higher than a power supply voltage supplied to the driving circuit, and
in response to the input signal having the first signal level, the second precharge circuit is configured to boost the second precharging voltage to be higher than the power supply voltage.

4. The driving circuit of claim 1, wherein
the first driving device and the second driving device comprise GaN-based enhancement-mode high-electron-mobility transistors (E-HEMT).

5. The driving circuit of claim 1, wherein
the first driving device and the second driving device comprise silicon-based enhancement-mode N-type transistors.

6. The driving circuit of claim 2, wherein
the first subcircuit further comprises a first inverter configured to convert the input signal to a first voltage signal for controlling the first precharge circuit, and
the second subcircuit further comprises a second inverter configured to convert the first voltage signal to a second voltage signal for controlling the second precharge circuit.

7. The driving circuit of claim 6, wherein
the first inverter comprises:
a first enhancement-mode high-electron-mobility transistor (E-HEMT) having a gate connected to the input signal, a drain connected to a first node, and a source connected to a ground voltage; and
a first depletion-mode HEMT (D-HEMT) having a gate connected to the first node, a drain connected to a power supply voltage, and a source connected to the first node, and
the second inverter comprises:
a second E-HEMT having a gate connected to the first voltage signal, a drain connected to a second node, and a source connected to the ground voltage; and
a second D-HEMT having a gate connected to the second node, a drain connected to the power supply voltage, and a source connected to the second node.

8. The driving circuit of claim 6, wherein
the first precharge circuit comprises:
a first diode, coupled between a power supply voltage and a first node;
a first enhancement-mode high-electron-mobility transistor (E-HEMT), having a gate connected to the first voltage signal, a drain connected to a second node, and a source connected to a ground voltage;
a first depletion-mode HEMT (D-HEMT), having a gate connected to the second node, a drain connected to the first node, and a source connected to the second node;
a second E-HEMT, having a gate connected to the first voltage signal, a drain connected to a third node, and a source connected to the ground voltage;
a third E-HEMT, having a gate connected to the second node, a drain connected to the power supply voltage, and a source connected to the third node; and
a first capacitor, having a first terminal connected to the first node, and a second terminal connected to the third node.

9. The driving circuit of claim 8, wherein
the first predriving circuit comprises:
a fourth E-HEMT, having a gate connected to the first voltage signal, a drain connected to a fourth node, and a source connected to the ground voltage; and
a fifth E-HEMT, having a gate connected to the third node, a drain connected to the power supply voltage, and a source connected to the fourth node, and
the first driving device comprises a gate connected to the fourth node, a drain connected to the power supply voltage, and a source connected to an output terminal of the driving circuit.

10. The driving circuit of claim 9, wherein
the second precharge circuit comprises:
a second diode, coupled between the power supply voltage and a fifth node;
a sixth E-HEMT, having a gate connected to the second voltage signal, a drain connected to a sixth node, and a source connected to the ground voltage;
a second D-HEMT, having a gate connected to the sixth node, a drain connected to the fifth node, and a source connected to the sixth node;
a seventh E-HEMT, having a gate connected to the second voltage signal, a drain connected to a seventh node, and a source connected to the ground voltage;
an eighth E-HEMT, having a gate connected to the sixth node, a drain connected to the power supply voltage, and a source connected to the seventh node; and
a second capacitor, having a first terminal connected to the fifth node, and a second terminal connected to the seventh node.

11. The driving circuit of claim 10, wherein
the second predriving circuit comprises:
a ninth E-HEMT, having a gate connected to the second voltage signal, a drain connected to an eighth node, and a source connected to the ground voltage; and
a tenth E-HEMT, having a gate connected to the seventh node, a drain connected to the power supply voltage, and a source connected to the eighth node, and
the second driving device comprises a gate connected to the eighth node, a drain connected to the output terminal of the driving circuit, and a source, connected to the ground voltage.

12. The driving circuit of claim 11, wherein
the first diode and the second diode correspondingly comprise an eleventh E-HEMT and a twelfth E-HEMT in a diode-connected configuration.

13. The driving circuit of claim 11, wherein
the first capacitor and the second capacitor comprise metal-insulator-metal (MIM) or metal-oxide-metal (MOM) capacitors.

14. Multi-stage precharging circuitry for a driving circuit, the multi-stage precharging circuitry comprising:
a first precharge circuit, configured to generate a first boost driving voltage higher than a power supply voltage supplied to the multi-stage precharging circuitry, in response to an input signal having a first signal level; and
a second precharge circuit, electrically connected to the first precharge circuit, and configured to generate a second boost driving voltage based on the first boost driving voltage, in response to the input signal having the first signal level.

15. The multi-stage precharging circuitry of claim 14, further comprising:
a first predriving circuit, electrically connected to the second precharge circuit and configured to drive a first driving device of the driving circuit,
wherein the first predriving circuit comprises a first predriving device configured to be fully turned on by the second boost driving voltage, in response to the input signal having the first signal level.

16. The multi-stage precharging circuitry of claim 14, further comprising:
a third precharge circuit, configured to generate a third boost driving voltage higher than the power supply voltage, in response to the input signal having a second signal level different from the first signal level; and
a fourth precharge circuit, electrically connected to the third precharge circuit, and configured to generate a fourth boost driving voltage based on the third boost driving voltage in response to the input signal having the second signal level.

17. The multi-stage precharging circuitry of claim 16, further comprising:
a first predriving circuit, electrically connected to the second precharge circuit and configured to drive a first driving device of the driving circuit, wherein the first predriving circuit comprises a first predriving device configured to be fully turned on by the second boost driving voltage, in response to the input signal having the first signal level; and
a second predriving circuit, electrically connected to the fourth precharge circuit and configured to drive a second driving device of the driving circuit, wherein the second predriving circuit comprises a second predriving device configured to be fully turned on by the fourth boost driving voltage, in response to the input signal having the second signal level.

18. The multi-stage precharging circuitry of claim 17, further comprising:
a first inverter, configured to convert the input signal to a first voltage signal for controlling the first precharge circuit; and
a second inverter, configured to convert the first voltage signal to a second voltage signal for controlling the third precharge circuit.

19. A method of operating a driving circuit, wherein the driving circuit comprises a first precharge circuit, a first predriving circuit, and a driving stage, the method comprising:
in response to an input signal being in a first logic state:
storing, by a first capacitor in the first precharge circuit, a first precharging voltage; and
in response to the input signal being in a second logic state different from the first logic state:
boosting, by the first precharge circuit using the stored first precharging voltage, a first driving voltage for the first predriving circuit, and
driving, by the first predriving circuit with the boosted first driving voltage, a first driving device in the driving stage to provide a first voltage corresponding to a power supply voltage to a power device.

20. The method of claim 19, wherein the driving circuit further comprises a second precharge circuit and a second predriving circuit, the method further comprising:
in response to the input signal being in the second logic state:
storing, by a second capacitor in the second precharge circuit, a second precharging voltage; and
in response to the input signal being in the first logic state:
boosting, by the second precharge circuit using the stored second precharging voltage, a second driving voltage for the second predriving circuit, and
driving, by the second predriving circuit with the boosted second driving voltage, a second driving device in the driving stage to provide a ground voltage to the power device.
